(19) United States
(12) Patent Application Publication
(10) Pub. No.: US 2017/0074943 A1
(43) Pub. Date: Mar. 16, 2017

(54) OPERATION STATE ESTIMATION APPARATUS AND OPERATION STATE ESTIMATION METHOD FOR ENERGY STORAGE DEVICE, AND ENERGY STORAGE SYSTEM

(71) Applicant: GS Yuasa International Ltd., Kyoto-shi (JP)

(72) Inventor: Yohei TAO, Kyoto-shi, Kyoto (JP)

(21) Appl. No.: 15/122,901

(22) PCT Filed: Mar. 12, 2015
(86) PCT No.: PCT/JP2015/001355

§ 371 Date: Aug. 31, 2016

(30) Foreign Application Priority Data
Mar. 28, 2014 (JP) 2014-069905

(51) Int. Cl. G01R 31/36

(52) U.S. Cl. CPC G01R 31/3651; G01R 31/3679

(57) ABSTRACT

An operation state estimation apparatus configured to estimate an operation state of an energy storage device includes a history acquirer configured to acquire a charge-discharge history of the energy storage device during a predetermined period, and a pattern data generator configured to generate pattern data in accordance with the acquired charge-discharge history, the pattern data being obtained by patterning data indicating repetitive variation out of data indicating variation in state quantity of the energy storage device during the predetermined period. An operation state estimation method of estimating an operation state of an energy storage device executed by a computer includes a history acquisition step of acquiring a charge-discharge history of the energy storage device during a predetermined period, and a pattern data generation step of generating pattern data in accordance with the acquired charge-discharge history.

### TECHNICAL FIELD

The present invention relates to an operation state estimation apparatus configured to estimate an operation state of an energy storage device, an operation state estimation method, and an energy storage system including an energy storage device and the operation state estimation apparatus.

### BACKGROUND ART

An energy storage device exemplified by a lithium ion secondary battery had been used as a power source of mobile equipment like a notebook computer or a mobile phone. The energy storage device has recently been applied to wider fields and has been used as a power source of an electric vehicle or the like.

There has conventionally been proposed a technique of estimating an operation state of such an energy storage device in accordance with information like a charge-discharge history and controlling the energy storage device (see Patent Document 1). This technique includes accumulating, in a memory, information on the energy storage device like the charge-discharge history and performing control of the energy storage device exemplified by charge-discharge control in accordance with the information accumulated in the memory.

### PRIOR ART DOCUMENT

### Patent Document

Patent Document 1: JP-A-2011-113759

### SUMMARY OF THE INVENTION

### Problem to be Solved by the Invention

However, the above conventional technique problematically requires a memory of large capacity because information on the energy storage device to be accumulated in the memory increases in volume as time elapses.

The present invention has been made in order to solve this problem, and an object thereof is to provide an operation state estimation apparatus and an operation state estimation method for an energy storage device, as well as an energy storage system, which enable reduction in volume of information to be accumulated in a memory.

### Means for Solving the Problem

In order to achieve the object mentioned above, an operation state estimation apparatus according to an aspect of the present invention is configured to estimate an operation state of an energy storage device, and includes: a history acquirer configured to acquire a charge-discharge history of the energy storage device during a predetermined period; and a pattern data generator configured to generate pattern data in accordance with the acquired charge-discharge history, the pattern data being obtained by patterning data indicating repetitive variation out of data indicating variation in state quantity of the energy storage device during the predetermined period.

The present invention is embodied by such an operation state estimation apparatus as well as by an energy storage system including an energy storage device and an operation state estimation apparatus configured to estimate an operation state of the energy storage device. The present invention is also embodied by an operation state estimation method including steps of characteristic processes executed by the operation state estimation apparatus. The present invention is also embodied by an integrated circuit including characteristic processors in the operation state estimation apparatus. The present invention is also embodied by a program configured to cause a computer to execute a characteristic process included in the operation state estimation method, and by a recording medium like a computer-readable compact disc-read only memory (CD-ROM) storing the program. Such a program is obviously distributable by means of a recording medium like a CD-ROM or through a transmission medium like the Internet.

### Advantage of the Invention

The operation state estimation apparatus for an energy storage device according to the present invention enables reduction in volume of information to be accumulated in a memory.

### BRIEF DESCRIPTION OF THE DRAWINGS

FIG. 1 is an external view of an energy storage system including an operation state estimation apparatus according to an embodiment of the present invention.

FIG. 2 is a block diagram depicting a functional configuration of the operation state estimation apparatus according to the embodiment of the present invention.

FIG. 3 is a chart of exemplary charge-discharge historical data according to the embodiment of the present invention.

FIG. 4 is a graph of exemplary pattern data generated by a pattern data generator according to the embodiment of the present invention.

FIG. 5A is a graph of exemplary test data referred to for estimation of a life of an energy storage device by a life estimator according to the embodiment of the present invention.

FIG. 5B is a graph of exemplary test data referred to for estimation of a life of an energy storage device by the life estimator according to the embodiment of the present invention.

FIG. 5C is a graph of exemplary test data referred to for estimation of a life of an energy storage device by the life estimator according to the embodiment of the present invention.

FIG. 6 is a flowchart of an exemplary process of estimating an operation state of an energy storage device by the operation state estimation apparatus according to the embodiment of the present invention.

FIG. 7 is a flowchart of an exemplary process of acquiring a charge-discharge history of an energy storage device by a history acquirer according to the embodiment of the present invention.

FIG. 8 is a flowchart of an exemplary process of generating pattern data by the pattern data generator according to the embodiment of the present invention.

FIG. 9 is a flowchart of an exemplary process of estimating a life of an energy storage device by the life estimator according to the embodiment of the present invention.

FIG. 10 is an explanatory graph of a process of estimating a capacity decrease ratio of an energy storage device by the life estimator according to the embodiment of the present invention.

FIG. 11 is an explanatory graph of the process of estimating a life of an energy storage device by the life estimator according to the embodiment of the present invention.

FIG. 12 is a block diagram depicting functional configurations of a first operation state estimation apparatus and a second operation state estimation apparatus according to a modification example 1 of the embodiment of the present invention.

FIG. 13 is a block diagram depicting functional configurations of a first operation state estimation apparatus and a second operation state estimation apparatus according to a modification example 2 of the embodiment of the present invention.

FIG. 14 is a flowchart of an exemplary process of acquiring a charge-discharge history of an energy storage device by a history acquirer according to the modification example 2 of the embodiment of the present invention.

FIG. 15 is a block diagram depicting a functional configuration of an operation state estimation apparatus according to a modification example 3 of the embodiment of the present invention.

FIG. 16 is a block diagram depicting a configuration, embodied by an integrated circuit, of the operation state estimation apparatus according to the embodiment of the present invention.

### MODE FOR CARRYING OUT THE INVENTION

The conventional technique described above problematically requires a memory of large capacity because information on an energy storage device to be accumulated in the memory increases in volume as time elapses.

Specifically, information on the energy storage device like a charge-discharge history needs to be accumulated in the memory at a short cycle for accurate estimation of an operation state of the energy storage device in the control of the energy storage device. A memory of large capacity is required because information on the energy storage device to be accumulated in the memory increases in volume as time elapses.

The present invention has been made in order to solve this problem, and an object thereof is to provide an operation state estimation apparatus and an operation state estimation method for an energy storage device, as well as an energy storage system, which enable reduction in volume of information to be accumulated in a memory.

In order to achieve the object mentioned above, an operation state estimation apparatus according to an aspect of the present invention is configured to estimate an operation state of an energy storage device, and includes: a history acquirer configured to acquire a charge-discharge history of the energy storage device during a predetermined period; and a pattern data generator configured to generate pattern data in accordance with the acquired charge-discharge history, the pattern data being obtained by patterning data indicating repetitive variation out of data indicating variation in state quantity of the energy storage device during the predetermined period.

This operation state estimation apparatus is configured to generate pattern data including patterned variation in state quantity of the energy storage device in accordance with the charge-discharge history of the energy storage device. In other words, the operation state estimation apparatus is configured to pattern a past charge-discharge history accumulated in the memory, so that there is no need to store in the memory a charge-discharge history referred to for generation of pattern data. The operation state estimation apparatus thus enables reduction in volume of information to be accumulated in the memory.

Optionally, the history acquirer may acquire, as the charge-discharge history, information including first information on at least one of a voltage or a current of the energy storage device during the predetermined period and information on a service period of the energy storage device, and the pattern data generator may generate the pattern data in accordance with a relation between second information on the state quantity of the energy storage device obtained from the first information, and the information on the service period of the energy storage device.

This operation state estimation apparatus is configured to generate pattern data in accordance with the relation between the second information on the state quantity of the energy storage device obtained from the first information on at least one of the voltage or the current of the energy storage device and the service period of the energy storage device. In other words, the operation state estimation apparatus is configured to generate pattern data from the voltage or the current of the energy storage device, and the service period thereof. The operation state estimation apparatus is thus configured to easily generate pattern data.

Optionally, the history acquirer may acquire, as the charge-discharge history, information including the first information during the predetermined period, information on a temperature of the energy storage device, and the information on the service period thereof, and the pattern data generator may generate the pattern data in accordance with a relation among the second information, the information on the temperature, and the information on the service period.

This operation state estimation apparatus is configured to generate pattern data in accordance with the relation among the second information, the temperature of the energy storage device, and the service period thereof. In other words, the operation state estimation apparatus is configured to generate pattern data also in accordance with the temperature of the energy storage device. The operation state estimation apparatus is thus configured to accurately generate pattern data also in consideration of influence by variation in temperature of the energy storage device.

Optionally, the operation state estimation apparatus may further include a first storage configured to store the charge-discharge history during the predetermined period. The history acquirer may acquire the charge-discharge history by reading out the charge-discharge history stored in the first storage. The pattern data generator may generate the pattern data in accordance with the acquired charge-discharge history, may write the generated pattern data in the first storage, and may erase the acquired charge-discharge history from the first storage.

This operation state estimation apparatus is configured to acquire a charge-discharge history from the memory, generate pattern data, write the pattern data in the memory, and erase the acquired charge-discharge history from the memory. In other words, the operation state estimation apparatus is configured to pattern a past charge-discharge history accumulated in the memory, so that there is no need to store in the memory the charge-discharge history thus patterned, and the operation state estimation apparatus erases the charge-discharge history from the memory. The operation state estimation apparatus thus enables reduction in volume of information to be accumulated in the memory.

Optionally, the operation state estimation apparatus may further include a detector connected to the energy storage device and configured to detect the charge-discharge history from the energy storage device, and the history acquirer may acquire the charge-discharge history detected by the detector.

This operation state estimation apparatus is configured to acquire a charge-discharge history by detecting the charge-discharge history from the energy storage device. The operation state estimation apparatus does not need to acquire any charge-discharge history from external equipment but is configured to self-detect a charge-discharge history to acquire the charge-discharge history.

Optionally, the operation state estimation apparatus may further include a communicator configured to receive the charge-discharge history from external equipment, and the history acquirer may acquire the charge-discharge history received by the communicator.

This operation state estimation apparatus is configured to acquire a charge-discharge history by receiving the charge-discharge history from external equipment. The operation state estimation apparatus does not need to self-detect any charge-discharge history but is configured to receive a charge-discharge history from external equipment to acquire the charge-discharge history.

Optionally, the operation state estimation apparatus may further include a life estimator configured to estimate a life of the energy storage device in accordance with the pattern data.

This operation state estimation apparatus is configured to estimate the life of the energy storage device in accordance with pattern data. The operation state estimation apparatus is thus configured to easily estimate the life of the energy storage device in accordance with data obtained by patterning a past history, with no need for complicated data processing. The operation state estimation apparatus is configured to estimate the life of the energy storage device in accordance with the past history without acquisition of any data (impedance, capacity, input-output characteristics, or the like) by some measurement means from the energy storage device at a time point of estimation.

Optionally, the operation state estimation apparatus may further include a second storage configured to store test data resulting from a life test of an energy storage device, the test data indicating capacity decrease under a test condition according to the pattern data. and the life estimator may estimate a capacity decrease ratio of the energy storage device during the predetermined period by collating the test data with the pattern data generated by the pattern data generator.

This operation state estimation apparatus is configured to estimate a capacity decrease ratio of the energy storage device during a predetermined period by collating the test data preliminarily stored with the pattern data. The operation state estimation apparatus is configured to estimate the capacity decrease ratio of the energy storage device during the predetermined period in accordance with the test data having accurate evaluation on performance of the energy storage device to accurately obtain the performance of the energy storage device at the end of the predetermined period.

Optionally, the life estimator may estimate the life of the energy storage device in accordance with the pattern data generated by the pattern data generator and the capacity decrease ratio of the energy storage device during the predetermined period.

This operation state estimation apparatus is configured to estimate the life of the energy storage device in accordance with the pattern data and the capacity decrease ratio of the energy storage device during the predetermined period. The operation state estimation apparatus is configured to estimate a capacity decrease ratio reflecting a future service condition of the energy storage device in accordance with the past history thereby to accurately estimate the life of the energy storage device.

Alternatively, an operation state estimation apparatus may be configured to estimate an operation state of an energy storage device, and may include: an acquirer configured to acquire pattern data obtained by patterning data indicating repetitive variation out of data indicating variation in state quantity of the energy storage device during a predetermined period; and a life estimator configured to estimate a life of the energy storage device in accordance with the acquired pattern data.

This operation state estimation apparatus is configured to acquire pattern data including patterned variation in state quantity of the energy storage device and estimate the life of the energy storage device in accordance with the pattern data. The operation state estimation apparatus is thus configured to easily estimate the life of the energy storage device in accordance with data obtained by patterning a past history, with no need for complicated data processing.

An operation state estimation apparatus for an energy storage device and an energy storage system including the operation state estimation apparatus according to an embodiment of the present invention will now be described below with reference to the drawings. The embodiment to be described below relates to preferred specific examples of the present invention. Numerical values, shapes, materials, constituent elements, disposition and connection of the constituent elements, steps, the order of the steps, and the like to be mentioned in the following embodiment are merely exemplary and are not intended to limit the scope of the present invention. Out of the constituent elements according to the following embodiment, those not recited in the independent claims on the superordinate concept of the present invention are to be described as optional constituent elements according to more preferred modes.

A configuration of an energy storage system 10 will initially be described.

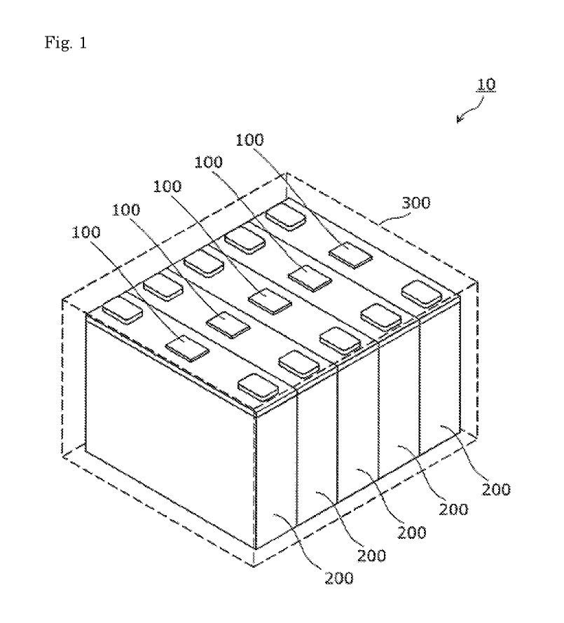

FIG. 1 is an external view of the energy storage system 10 including an operation state estimation apparatus 100 according to the embodiment of the present invention.

As depicted in this figure, the energy storage system 10 includes a plurality of (five in the figure) operation state estimation apparatuses 100, a plurality of (five in the figure) energy storage devices 200, and a case 300 accommodating the plurality of operation state estimation apparatuses 100 and the plurality of energy storage devices 200. Specifically, each of the operation state estimation apparatuses 100 is provided to a corresponding one of the energy storage devices 200.

Each of the operation state estimation apparatuses 100 is a tabular circuit board disposed above a corresponding one of the energy storage devices 200 and equipped with a circuit configured to estimate an operation state of the energy storage device 200. Specifically, each of the operation state estimation apparatuses 100 is connected to a corresponding one of the energy storage devices 200 and is configured to acquire information from the energy storage device 200 and estimate an operation state of the energy storage device 200.

Each of the operation state estimation apparatuses 100 herein is disposed above a corresponding one of the energy storage devices 200. However, the operation state estimation apparatuses 100 can be disposed anywhere. Furthermore, the operation state estimation apparatuses 100 are not particularly limited in terms of their shape.

The number of the operation state estimation apparatuses 100 is not limited to five, but can be any other number more than one or can be one. Specifically, one operation state estimation apparatus 100 can be provided correspondingly to a plurality of energy storage devices 200, or a plurality of operation state estimation apparatuses 100 can be provided correspondingly to a single energy storage device 200. In other words, any number of operation state estimation apparatuses 100 can be connected to any number of energy storage devices 200. The operation state estimation apparatuses 100 will be described later in terms of their detailed functional configuration.

The energy storage device 200 is a secondary battery configured to charge and discharge electricity, more particularly, a nonaqueous electrolyte secondary battery like a lithium ion secondary battery. According to this figure, the five energy storage devices 200 in a rectangular shape are disposed in series to configure an assembled battery. The number of the energy storage devices 200 is not limited to five, but can be any other number more than one or can be one. Furthermore, the energy storage devices 200 are not particularly limited in terms of their shape.

The energy storage device 200 includes a positive electrode and a negative electrode. The positive electrode includes positive electrode substrate foil in a long belt shape made from aluminum, aluminum alloy, or the like, and a positive active material layer provided on the positive electrode substrate foil. The negative electrode includes negative electrode substrate foil in a long belt shape made from copper, copper alloy, or the like, and a negative active material layer provided on the negative electrode substrate foil. A positive active material in the positive active material layer or a negative active material in the negative active material layer can be any appropriate known material if the positive active material or the negative active material can occlude and discharge lithium ions.

The energy storage device 200 is preferably a lithium ion secondary battery including layered lithium transition metal oxide as the positive active material. Specifically, preferred examples of the positive active material include layered lithium transition metal oxide like Li₁₊ₓM_{1-y}O₂ (M denotes one or at least two transition metal elements selected from Fe, Ni, Mn, Co, and the like, 0≦x<⅓, and 0≦y<⅓) typified by LiNi_{1/3}Co_{1/3}Mn_{1/3}O₂. The positive active material can be a mixture of the layered lithium transition metal oxide and spinel lithium-manganese oxide like LiMn₂O₄ or LiMn_{1.5}Ni_{0.5}O₄, an olivine positive active material like LiFePO₄, or the like.

Examples of the negative active material include lithium metal, lithium alloy (lithium metal containing alloy like lithium-silicon, lithium-aluminum, lithium-lead, lithium-tin, lithium-aluminum-tin, lithium-gallium, or wood's alloy), as well as lithium occludable and dischargeable alloy, a carbon material (e.g. graphite, hardly graphitizable carbon, easily graphitizable carbon, low-temperature baked carbon, or amorphous carbon), silicon oxide, metal oxide, lithium metal oxide (e.g. Li₄Ti₅O₁₂), a polyphosphoric acid compound, and a compound of transition metal and one of the group 14 to 16 elements like Co₃O₄ or Fe₂P typically referred to as a conversion negative electrode.

The energy storage device 200 is not limited to the nonaqueous electrolyte secondary battery, but can be a secondary battery other than the nonaqueous electrolyte secondary battery or can be a capacitor.

The operation state estimation apparatus 100 will be described next in terms of its detailed functional configuration.

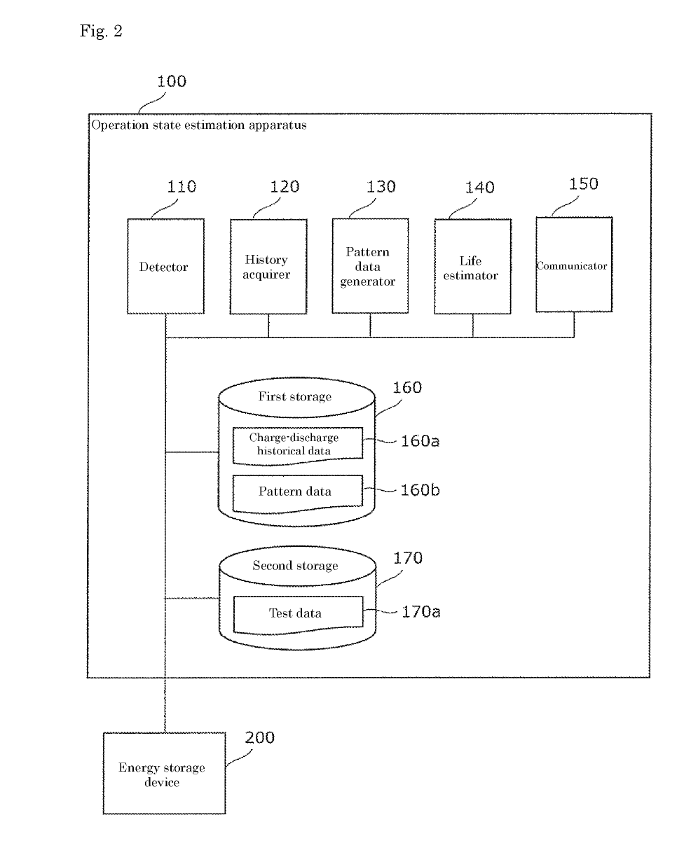

FIG. 2 is a block diagram depicting the functional configuration of the operation state estimation apparatus 100 according to the embodiment of the present invention.

The operation state estimation apparatus 100 is configured to estimate an operation state of the energy storage device 200. As depicted in this figure, the operation state estimation apparatus 100 includes a detector 110, a history acquirer 120, a pattern data generator 130, a life estimator 140, a communicator 150, a first storage 160, and a second storage 170.

The first storage 160 corresponds to a storage area of a nonvolatile memory configured to store a charge-discharge history during a predetermined period and the like. The first storage 160 stores charge-discharge historical data 160a and pattern data 160b. The second storage 170 corresponds to a storage area of a nonvolatile memory configured to store test data resulting from a life test of the energy storage device 200. The second storage 170 stores test data 170a.

A nonvolatile memory is a recording medium with no power source and is exemplified by a read only memory (ROM), a flash memory, a magnetic storage unit, an optical disk, and the like. Such a nonvolatile memory is a non-transitory recording medium for reading and writing. Examples of the nonvolatile memory include a paper recording medium with printing, like a paper tape.

The first storage 160 and the second storage 170 can correspond to the storage areas separately provided in a single nonvolatile memory, or the storage areas respectively provided in different nonvolatile memories.

The detector 110 is connected to the energy storage device 200 and is configured to detect a charge-discharge history from the energy storage device 200. Specifically, the detector 110 is electrically connected to an electrode terminal of the energy storage device 200 mounted with the detector 110 by way of wire like leading wire. The detector 110 is configured to detect a charge-discharge history from the energy storage device 200 by way of the wire during a predetermined period.

Specifically, the detector 110 is configured to constantly monitor the state of the energy storage device 200 and detect a charge-discharge history when predetermined variation is found in the state of the energy storage device 200. For example, the detector 110 is configured to monitor variation in voltage of the energy storage device 200 and detect a charge-discharge history assuming that the energy storage device 200 charges or discharges in a case where a voltage difference exceeds 1% of the current voltage. In this case, the detector 110 can detect a charge-discharge history when variation in voltage of the energy storage device 200 exceeds 1%. In other words, the detector 110 detects a charge-discharge history at a sampling cycle of 1% as variation in voltage of the energy storage device 200.

Timing of detecting a charge-discharge history is not limited to the above case and any sampling cycle is applicable. For example, the detector 110 may be configured to detect a charge-discharge history at a sampling cycle of one second as a service period.

A charge-discharge history is a past operation history of the energy storage device 200, and includes information on a period of charge or discharge by the energy storage device 200 (service period), information on charge or discharge by the energy storage device 200 during the service period, or the like.

Specifically, information on the service period of the energy storage device 200 includes a date (day/month/year) and time of charge or discharge by the energy storage device 200, a cumulative service period during which the energy storage device 200 is used, or the like.

The cumulative service period has a cumulative value of service periods of the energy storage device 200, and particularly indicates a total period obtained by integrating service periods of the energy storage device 200 from the start of use of the energy storage device 200 to a predetermined time point. In a case where the energy storage device 200 is used intermittently, the cumulative service period is obtained by subtracting non-service periods during which the energy storage device 200 is not used. The non-service periods may not be subtracted precisely, but the cumulative service period can indicate an entire period from the start of use of the energy storage device 200 to the predetermined time point, inclusive of the non-service periods. The cumulative service period preferably has a unit of time (hour, minute, or second) or a cycle (the number of charge and discharge), but can have any unit indicating a period exemplified by month or day.

Information on charge or discharge by the energy storage device 200 indicates a voltage, a current, a temperature, a battery state, or the like upon charge or discharge by the energy storage device 200, and is detected by the detector 110 in a case where the energy storage device 200 is assumed to charge or discharge.

A temperature in this case is a temperature of the energy storage device 200. The detector 110 can be configured to measure the temperature of the energy storage device 200 by means of a thermometer provided to a container or the electrode terminal of the energy storage device 200, or can be configured to measure an temperature around the energy storage device 200 by means of a thermometer. The detector 110 may be configured to acquire a temperature of a region where the energy storage device 200 is used (an ambient temperature).

A battery state is information on a state of the energy storage device 200 and is exemplified by a charge state, a discharge state, or a standby state (a state without charge or discharge). Such information on the battery state is unnecessary in a case where the battery state is presumed from information on a voltage or a current of the energy storage device 200.

The detector 110 is configured to subsequently write a detected charge-discharge history in the charge-discharge historical data 160a stored in the first storage 160.

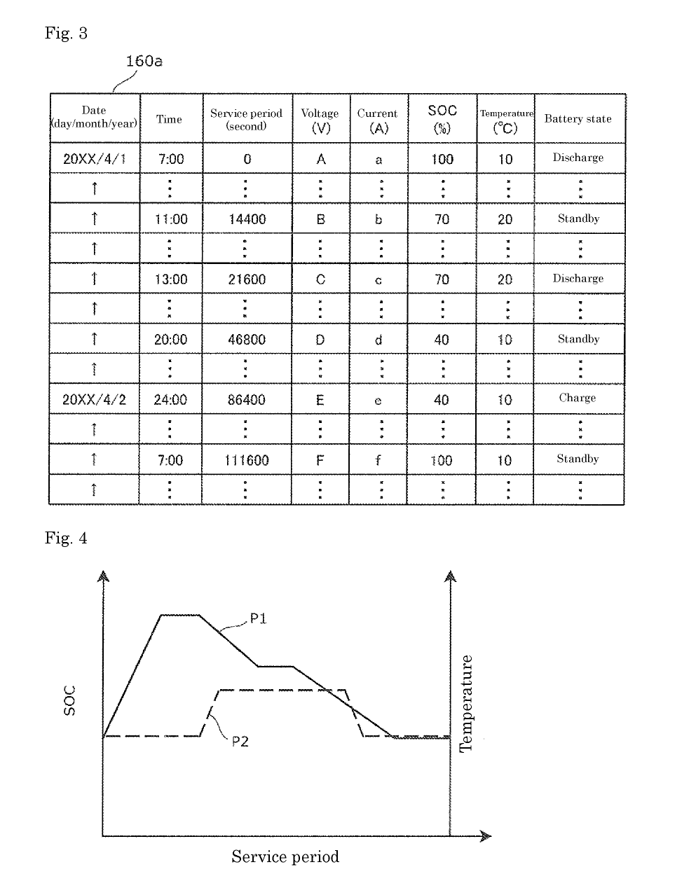

FIG. 3 is a chart exemplifying the charge-discharge historical data 160a according to the embodiment of the present invention.

The charge-discharge historical data 160a is a group of data on a charge-discharge history as a past operation history of the energy storage device 200 during a predetermined period. As indicated in this figure, the charge-discharge historical data 160a is a data table correspondingly indicating fields “date”, “time”, “service period”, “voltage”, “current”, “SOC”, “temperature”, and “battery state”.

The fields “date” and “time” include a date (day/month/year) and time as information on a time point of charge or discharge by the energy storage device 200, and the field “service period” includes a value indicating a cumulative service period of the energy storage device 200. The detector 110 is configured to measure time by means of a timer or the like, acquire (detect) the date (day/month/year), the time, and the cumulative service period, and write the information in the fields “date”, “time”, and “service period”. The detector 110 may be configured to calculate the cumulative service period in accordance with information included in the fields “date” and “time” and write the cumulative service period in the field “service period”.

The fields “voltage”, “current”, “temperature”, and “battery state” include, as information on charge or discharge by the energy storage device 200, information on a voltage, a current, a temperature, and a battery state upon charge or discharge by the energy storage device 200. In other words, the detector 110 is configured to acquire (detect) a voltage, a current, a temperature, and a battery state of the energy storage device 200 and write the information in the fields “voltage”, “current”, “temperature”, and “battery state”.

The field “SOC” includes information on a state of charge (SOC) of the energy storage device 200 upon charge or discharge by the energy storage device 200. The SOC is calculated by the pattern data generator 130 to be described later as information on a state quantity of the energy storage device 200 and is written in the field “SOC”. A process of calculating the SOC by the pattern data generator 130 will be described later.

With reference to FIG. 2 again, the history acquirer 120 is configured to acquire a charge-discharge history of the energy storage device 200 during a predetermined period. In other words, the history acquirer 120 is configured to acquire a charge-discharge history detected by the detector 110. Specifically, the history acquirer 120 acquires, as a charge-discharge history, information including first information on at least one of a voltage or a current of the energy storage device 200 during a predetermined period and information on a service period of the energy storage device 200. More specifically, the history acquirer 120 acquires, as the charge-discharge history, information including the first information during the predetermined period, information on a temperature of the energy storage device 200, and the information on the service period.

The history acquirer 120 is configured to read a charge-discharge history out of the charge-discharge historical data 160a in the first storage 160 to acquire the charge-discharge history. A charge-discharge history acquired by the history acquirer 120 is, as described above, information including the first information on at least one of a voltage or a current of the energy storage device 200 during a predetermined period, information on a temperature of the energy storage device 200, and information on a service period of the energy storage device 200.

Specifically, the history acquirer 120 is configured to acquire the first information as data on at least one of a voltage or a current during a predetermined period, a temperature during the predetermined period, and a service period during the predetermined period, out of data in the fields “voltage”, “current”, “temperature”, and “service period” in the charge-discharge historical data 160a.

A predetermined period corresponds to a period for generation of pattern data by the pattern data generator 130 to be described later, and is a period from the start of use of the energy storage device 200 to the current time point in the present embodiment. The predetermined period is not limited to the period described above, but the start time point can be set at the end of a certain period after the start of use of the energy storage device 200 and the end time point can be set at a time point ahead of the current time point by a certain period.

The pattern data generator 130 is configured to generate and acquire pattern data. The pattern data generator 130 generates pattern data obtained by patterning data indicating repetitive variation out of data indicating variation in state quantity of the energy storage device 200 during the predetermined period in accordance with a charge-discharge history acquired by the history acquirer 120. Specifically, the pattern data generator 130 is configured to calculate second information on a state quantity from the first information to generate pattern data. The pattern data generator 130 also functions as an acquirer configured to acquire generated pattern data.

The pattern data generator 130 is configured to calculate the second information on a state quantity of the energy storage device 200 in accordance with the first information on at least one of the voltage or the current of the energy storage device 200 during the predetermined period.

A state quantity of the energy storage device 200 has a numerical value indicating a state of the energy storage device 200, and is exemplified by a voltage or a current of the energy storage device 200, charge-discharge capacity indicating a state of charge or discharge by the energy storage device 200, or the like. In the present embodiment, a state quantity of the energy storage device 200 corresponds to charge-discharge capacity of the energy storage device 200, and the second information on a state quantity of the energy storage device 200 corresponds to an SOC of the energy storage device 200.

The pattern data generator 130 is configured to calculate an SOC by estimating the SOC from a voltage value of the energy storage device 200 in accordance with an SOC-OCV characteristic indicating a relation between an SOC and an open circuit voltage (OCV) or the like. The pattern data generator 130 may be configured to calculate an SOC from a current value of the energy storage device 200 in accordance with a current integration method of integrating charge-discharge currents to estimate the SOC.

The pattern data generator 130 is configured to generate pattern data in accordance with a relation between the second information (SOC) on charge-discharge capacity as a state quantity of the energy storage device 200 obtained from the first information, and information on a service period of the energy storage device 200. Specifically, the pattern data generator 130 generates pattern data in accordance with a relation among the second information (SOC), information on a temperature of the energy storage device 200, and information on a service period thereof.

FIG. 4 is a graph of exemplary pattern data generated by the pattern data generator 130 according to the embodiment of the present invention.

Pattern data is a data indicating an operation pattern of the energy storage device 200. Specifically, pattern data is a group of data on a relation among an SOC of the energy storage device 200, a temperature of the energy storage device 200, and a service period of the energy storage device 200, and is graphically exemplified by an indication P1 or an indication P2 in this graph. The indication P1 corresponds to a relation between an SOC and a service period of the energy storage device 200 whereas the indication P2 corresponds to a relation between a temperature and a service period of the energy storage device 200.

Pattern data is obtained by patterning data indicating repetitive variation out of data indicating variation in charge-discharge capacity as a state quantity (variation in SOC) of the energy storage device 200 during a predetermined period. In a case where variation as in the indication P1 or the indication P2 repeats during a predetermined period, data indicating variation as in the indication P1 or the indication P2 is generated as pattern data.

For example, if charge and discharge are repeated with variation as in the indication P1 or the indication P2 every day on weekdays, data as in the indication P1 or the indication P2 is generated as pattern data for weekdays. Similarly, pattern data for weekends is also generated. Repetition of exactly same charge and discharge (exactly same as in the indication P1 or the indication P2) is not required for generation of pattern data, a certain deviation is acceptable. Such a deviation is appropriately set by a setting by a user or the like.

In this manner, the pattern data generator 130 generates a plurality of pattern data during the predetermined period. The pattern data generator 130 may be configured to generate a single pattern data in a case where there is only one charge-discharge pattern.

The pattern data generator 130 is configured to write generated pattern data in the pattern data 160b stored in the first storage 160. The pattern data generator 130 can be configured to write pattern data in the pattern data 160b in a graphic form like the indication P1 or the indication P2, or can be configured to write pattern data in the pattern data 160b in a form of a data group (data table) for generation of the graphic indication.

The pattern data generator 130 is further configured to erase a charge-discharge history acquired by the history acquirer 120 for generation of pattern data from the charge-discharge historical data 160a in the first storage 160. The charge-discharge history is patterned as pattern data and does not need to be kept in the charge-discharge historical data 160a. The charge-discharge history can thus be erased from the charge-discharge historical data 160a.

With reference to FIG. 2 again, the life estimator 140 is configured to estimate a life of the energy storage device 200 in accordance with pattern data generated by the pattern data generator 130. Specifically, the life estimator 140 collates test data resulting from a life test of the energy storage device 200 with pattern data generated by the pattern data generator 130 to estimate a capacity decrease ratio of the energy storage device 200 during the predetermined period and estimate the life of the energy storage device 200.

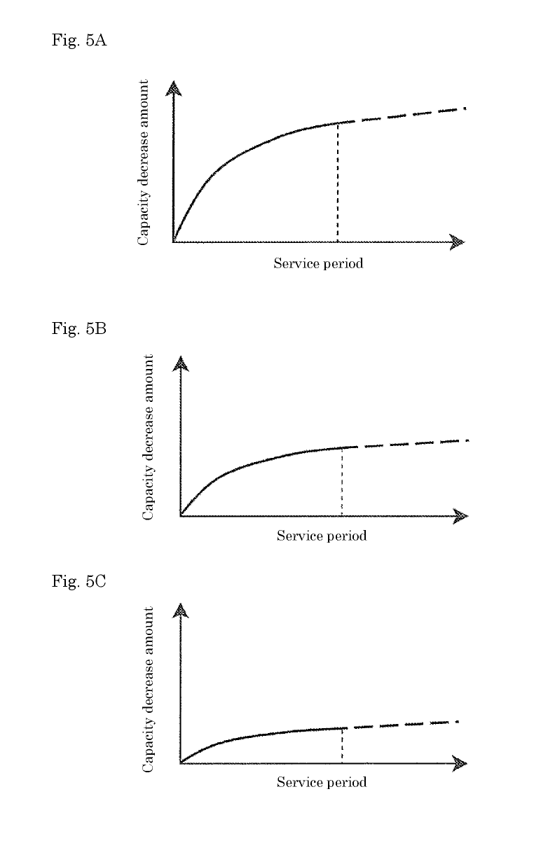

FIGS. 5A to 5C are graphs of exemplary test data referred to for estimation of a life of the energy storage device 200 by the life estimator 140 according to the embodiment of the present invention.

The test data results from the life test of the energy storage device 200 and indicates capacity decrease (a capacity decrease amount or a capacity decrease ratio) under a test condition according to pattern data generated by the pattern data generator 130. The test data is graphically exemplified indications in FIGS. 5A to 5C.

The test data is preliminarily stored in the test data 170a in the second storage 170. The test data is written in the test data 170a in a graphic form as in FIGS. 5A to 5C, or is written in the test data 170a in a form of a data group (data table) for generation of the graphic indication.

The graph in FIG. 5A relates to a capacity decrease amount of the energy storage device 200 in cycle deterioration according to a result of a life test in a case where the energy storage device 200 repetitively charges and discharges at 20° C., for example. The graph in FIG. 5B relates to a capacity decrease amount of the energy storage device 200 in deterioration due to leaving according to a result of a life test in a case where the energy storage device 200 is left at 10° C. and the SOC of 90%, for example. The graph in FIG. 5C relates to a capacity decrease amount of the energy storage device 200 in deterioration due to leaving according to a result of a life test in a case where the energy storage device 200 is left at 10° C. and the SOC of 20%. The indications in these graphs may be a capacity decrease ratio of the energy storage device 200.

In a case where pattern data generated by the pattern data generator 130 includes charge and discharge at 20° C., leaving at 10° C. and the SOC of 90%, and leaving at 10° C. and the SOC of 20%, test data thereof are applicable. Specifically, the life estimator 140 is configured to estimate a capacity decrease amount (or a capacity decrease ratio) of the energy storage device 200 in accordance with test data of cycle deterioration at 20° C., deterioration due to leaving at 10° C. and the SOC of 90%, deterioration due to leaving at 10° C. and the SOC of 20%, or the like as indicated in FIGS. 5A to 5C.

More specifically, the life estimator 140 is configured to calculate a capacity decrease amount (or a capacity decrease ratio) of the energy storage device 200 during a predetermined period by multiplying the number of repetition of pattern data generated by the pattern data generator 130 during the predetermined period by the capacity decrease amount of the energy storage device 200 calculated in accordance with FIGS. 5A to 5C, for example.

As described above, the test data 170a in the second storage 170 preliminarily includes test data under various conditions. The life estimator 140 is configured to read, out of the test data 170a, test data on a capacity decrease amount (or a capacity decrease ratio) under a test condition according to pattern data generated by the pattern data generator 130. The life estimator 140 is configured to collate the test data with the pattern data generated by the pattern data generator 130 to estimate a capacity decrease amount (or a capacity decrease ratio) of the energy storage device 200 during the predetermined period.

The life estimator 140 is also configured to estimate a life of the energy storage device 200 in accordance with the pattern data generated by the pattern data generator 130 and the capacity decrease amount (or the capacity decrease ratio) of the energy storage device 200 during the predetermined period.

With reference to FIG. 2 again, the communicator 150 is a processor configured to transmit and receive data to and from external equipment. Specifically, the communicator 150 is a processor configured to communicate by infrared communication, the Internet, a wireless local area network (LAN), Wi-Fi, Bluetooth (registered trademark), Zigbee (registered trademark), radio frequency identification (RFID), a bar code, a QR code (registered trademark), or the like.

For example, the communicator 150 is configured to transmit, to external equipment, pattern data generated by the pattern data generator 130, a life of the energy storage device 200 estimated by the life estimator 140, and the like, receive test data from external equipment, and adds the received test data to the test data 170a.

Described in detail next is a process of estimating an operation state of the energy storage device 200 by the operation state estimation apparatus 100.

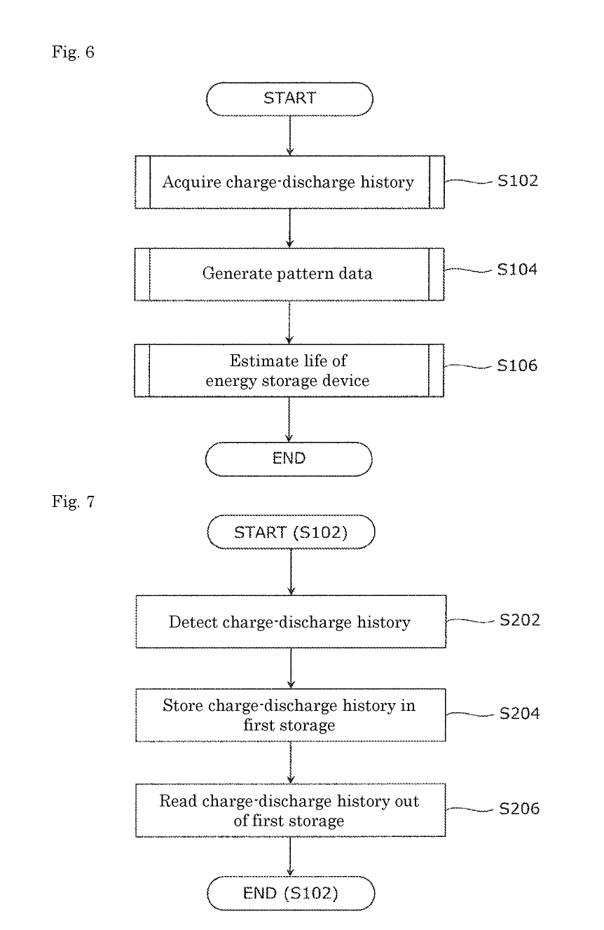

FIG. 6 is a flowchart of an exemplary process of estimating an operation state of the energy storage device 200 by the operation state estimation apparatus 100 according to the embodiment of the present invention.

As depicted in this figure, the history acquirer 120 initially acquires a charge-discharge history of the energy storage device 200 during a predetermined period (S102). A process of acquiring a charge-discharge history of the energy storage device 200 by the history acquirer 120 will be described in detail later.

The pattern data generator 130 subsequently generates pattern data during the predetermined period in accordance with the charge-discharge history acquired by the history acquirer 120 (S104). A process of generating pattern data by the pattern data generator 130 will be described in detail later.

The life estimator 140 then estimates a life of the energy storage device 200 in accordance with the pattern data generated by the pattern data generator 130 (S106). The process of estimating a life of the energy storage device 200 by the life estimator 140 will be described in detail later.

This is the end of the process of estimating an operation state of the energy storage device 200 by the operation state estimation apparatus 100.

Described in detail next is the process of acquiring a charge-discharge history of the energy storage device 200 by the history acquirer 120 (S102 in FIG. 6).

FIG. 7 is a flowchart of an exemplary process of acquiring a charge-discharge history of the energy storage device 200 by the history acquirer 120 according to the embodiment of the present invention.

As depicted in this figure, the detector 110 initially detects a charge-discharge history from the energy storage device 200 (S202). Specifically, the detector 110 detects a date (day/month/year) and time of charge or discharge by the energy storage device 200 and calculates a service period of the energy storage device 200. The detector 110 also detects a voltage, a current, a temperature, a battery state, or the like upon charge or discharge by the energy storage device 200.

The detector 110 then stores the detected charge-discharge history in the first storage 160 (S204). Specifically, the detector 110 writes the detected charge-discharge history in the charge-discharge historical data 160a stored in the first storage 160. In other words, the detector 110 writes, in the charge-discharge historical data 160a, the date (day/month/year) and the time of charge or discharge by the energy storage device 200, the service period of the energy storage device 200, the voltage, the current, the temperature, the battery state, or the like upon charge or discharge by the energy storage device 200.

The history acquirer 120 acquires the charge-discharge history detected by the detector 110 by reading out of the first storage 160 (S206). Specifically, the history acquirer 120 reads a charge-discharge history out of the charge-discharge historical data 160a in the first storage 160 to acquire the charge-discharge history. In other words, the history acquirer 120 reads, out of the charge-discharge historical data 160a, the first information on at least one of a voltage or a current of the energy storage device 200 during a predetermined period, a temperature of the energy storage device 200, and information on a service period of the energy storage device 200, and acquires information including these pieces of information, as a charge-discharge history.

This is the end of the process of acquiring a charge-discharge history of the energy storage device 200 by the history acquirer 120 (S102 in FIG. 6).

Described in detail next is the process of generating pattern data by the pattern data generator 130 (S104 in FIG. 6).

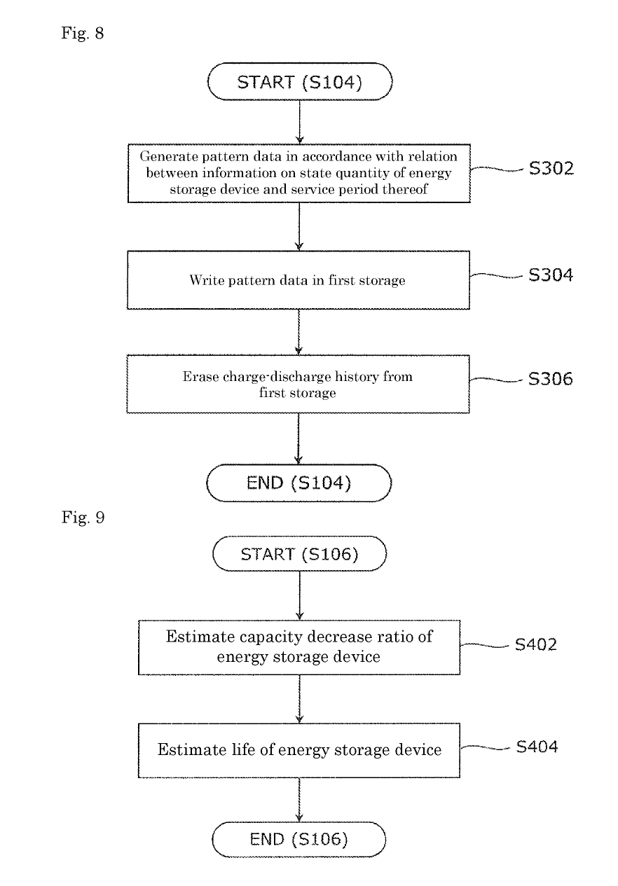

FIG. 8 is a flowchart of an exemplary process of generating pattern data by the pattern data generator 130 according to the embodiment of the present invention.

As depicted in this figure, the pattern data generator 130 initially generates pattern data in accordance with a relation between information on a state quantity of the energy storage device 200 and information on a service period of the energy storage device 200 (S302). Specifically, the pattern data generator 130 generates pattern data in accordance with a relation among the second information (SOC) on charge-discharge capacity as a state quantity of the energy storage device 200 obtained from the first information, information on a temperature of the energy storage device 200, and information on a service period of the energy storage device 200.

The pattern data generator 130 generates pattern data obtained by patterning data indicating repetitive variation out of data indicating variation in charge-discharge capacity as a state quantity of the energy storage device 200 during the predetermined period in accordance with the charge-discharge history acquired by the history acquirer 120.

The pattern data generator 130 subsequently writes the generated pattern data in the pattern data 160b stored in the first storage 160 (S304).

The pattern data generator 130 then erases the charge-discharge history referred to for generation of the pattern data from the charge-discharge historical data 160a in the first storage 160 (S306).

This is the end of the process of generating pattern data by the pattern data generator 130 (S104 in FIG. 6).

Described in detail next is the process of estimating a life of the energy storage device 200 by the life estimator 140 (S106 in FIG. 6).

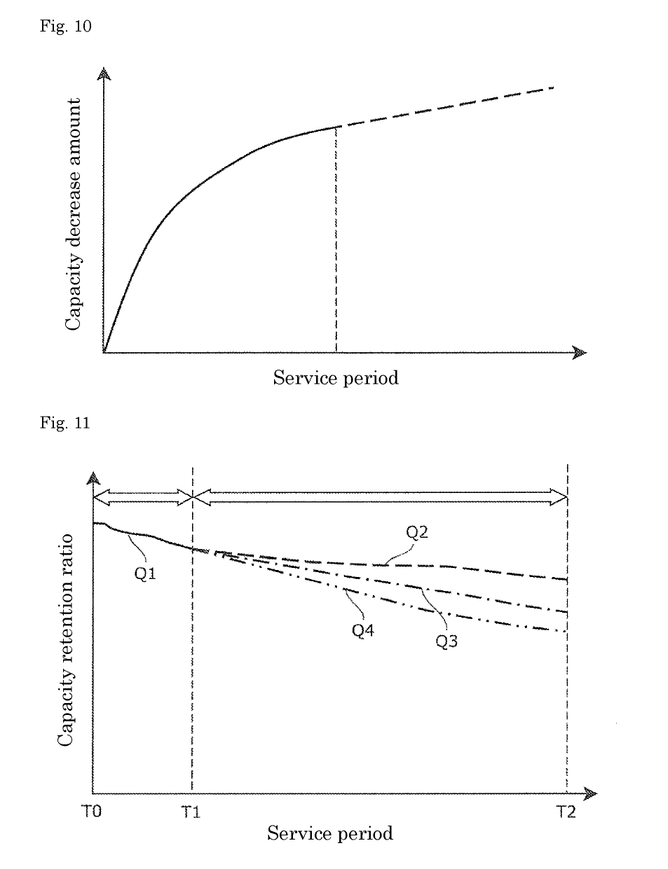

FIG. 9 is a flowchart of an exemplary process of estimating a life of the energy storage device 200 by the life estimator 140 according to the embodiment of the present invention. FIG. 10 is an explanatory graph of a process of estimating a capacity decrease ratio of the energy storage device 200 by the life estimator 140 according to the embodiment of the present invention. FIG. 11 is an explanatory graph of the process of estimating a life of the energy storage device 200 by the life estimator 140 according to the embodiment of the present invention.

As depicted in FIG. 9, the life estimator 140 initially collates test data resulting from a life test of the energy storage device 200 with pattern data generated by the pattern data generator 130 to estimate a capacity decrease ratio of the energy storage device 200 during a predetermined period (S402).

Specifically, the life estimator 140 reads, out of the test data 170a, test data on a capacity decrease amount (or a capacity decrease ratio) under a test condition according to the pattern data generated by the pattern data generator 130. The life estimator 140 subsequently collates the test data with the pattern data generated by the pattern data generator 130 to estimate a capacity decrease amount (or a capacity decrease ratio) of the energy storage device 200 during the predetermined period as indicated in FIG. 10.

The life estimator 140 then estimates a life of the energy storage device 200 in accordance with the pattern data generated by the pattern data generator 130 and the capacity decrease amount (or the capacity decrease ratio) of the energy storage device 200 during the predetermined period (S404).

Specifically, as indicated in FIG. 11, the life estimator 140 estimates an indication Q1 of a capacity retention ratio of the energy storage device 200 during a predetermined period (T0 to T1) in accordance with a capacity decrease amount (or a capacity decrease ratio) of the energy storage device 200 during the predetermined period (T0 to T1). The life estimator 140 then estimates indications Q2 to Q4 of a life of the energy storage device 200 in accordance with the pattern data generated by the pattern data generator 130 and the indication Q1 of the capacity retention ratio of the energy storage device 200.

In other words, the life estimator 140 acquires operation patterns 1 to 3 of the energy storage device 200 during a coming period (T1 to T2) from external equipment, and estimates the graphs Q2 to Q4 of the life of the energy storage device 200 according to the operation patterns 1 to 3. The life estimator 140 may be configured to predict an operation pattern of the energy storage device 200 in the coming period (T1 to T2) in accordance with an operation history of the energy storage device 200 during the past period (T0 to T1) to estimate the life (capacity retention ratio) of the energy storage device 200.

This is the end of the process of estimating a life of the energy storage device 200 by the life estimator 140 (S106 in FIG. 6).

As described above, the operation state estimation apparatus 100 according to the embodiment of the present invention is configured to generate pattern data including patterned variation in charge-discharge capacity of the energy storage device 200 in accordance with a charge-discharge history of the energy storage device 200. In other words, the operation state estimation apparatus 100 is configured to pattern a past charge-discharge history accumulated in the memory, so that there is no need to store in the memory the patterned charge-discharge history. The operation state estimation apparatus 100 thus enables reduction in volume of information to be accumulated in the memory.

The operation state estimation apparatus 100 is configured to generate pattern data in accordance with the relation between the second information on a state quantity (charge-discharge capacity) of the energy storage device 200 obtained from the first information on at least one of a voltage or a current of the energy storage device 200 and a service period of the energy storage device 200. In other words, the operation state estimation apparatus 100 is configured to generate pattern data from a voltage or a current of the energy storage device 200, and a service period thereof. The operation state estimation apparatus 100 is thus configured to easily generate pattern data.

This operation state estimation apparatus 100 is configured to generate pattern data in accordance with the relation among the second information, a temperature of the energy storage device 200, and a service period thereof. In other words, the operation state estimation apparatus 100 is configured to generate pattern data also in accordance with the temperature of the energy storage device 200. The operation state estimation apparatus 100 is thus configured to accurately generate pattern data also in consideration of influence by variation in temperature of the energy storage device 200.

The operation state estimation apparatus 100 is configured to acquire a charge-discharge history from the memory, generate pattern data, write the pattern data in the memory, and erase the acquired charge-discharge history from the memory. In other words, the operation state estimation apparatus is configured to pattern a past charge-discharge history accumulated in the memory, so that there is no need to store in the memory the charge-discharge history thus patterned and the operation state estimation apparatus 100 erases the charge-discharge history from the memory. The operation state estimation apparatus 100 thus enables reduction in volume of information to be accumulated in the memory.

The operation state estimation apparatus 100 is further configured to acquire a charge-discharge history by detecting the charge-discharge history from the energy storage device 200. The operation state estimation apparatus 100 does not need to acquire a charge-discharge history from external equipment but is configured to self-detect a charge-discharge history to acquire the charge-discharge history.

The operation state estimation apparatus 100 is configured to estimate a life of the energy storage device 200 in accordance with pattern data. The operation state estimation apparatus 100 is thus configured to easily estimate a life of the energy storage device 200 in accordance with data obtained by patterning a past history, with no need for complicated data processing.

The operation state estimation apparatus 100 is configured to estimate a life of the energy storage device 200 in accordance with a past history without acquisition of any data (impedance, capacity, input-output characteristics, or the like) by some measurement means from the energy storage device 200 at a time point of estimation.

This operation state estimation apparatus 100 is configured to estimate a capacity decrease ratio of the energy storage device 200 during a predetermined period by collating test data preliminarily stored with pattern data. The operation state estimation apparatus 100 is thus configured to estimate a capacity decrease ratio of the energy storage device 200 during a predetermined period in accordance with test data having accurate evaluation of performance of the energy storage device 200 to accurately obtain the performance of the energy storage device 200 at the end of the predetermined period.

This operation state estimation apparatus 100 is also configured to estimate a life of the energy storage device 200 in accordance with pattern data and a capacity decrease ratio of the energy storage device 200 during a predetermined period. The operation state estimation apparatus 100 is configured to estimate a capacity decrease ratio reflecting a future service condition of the energy storage device 200 in accordance with the past history thereby to accurately estimate the life of the energy storage device 200.

### Modification Example 1

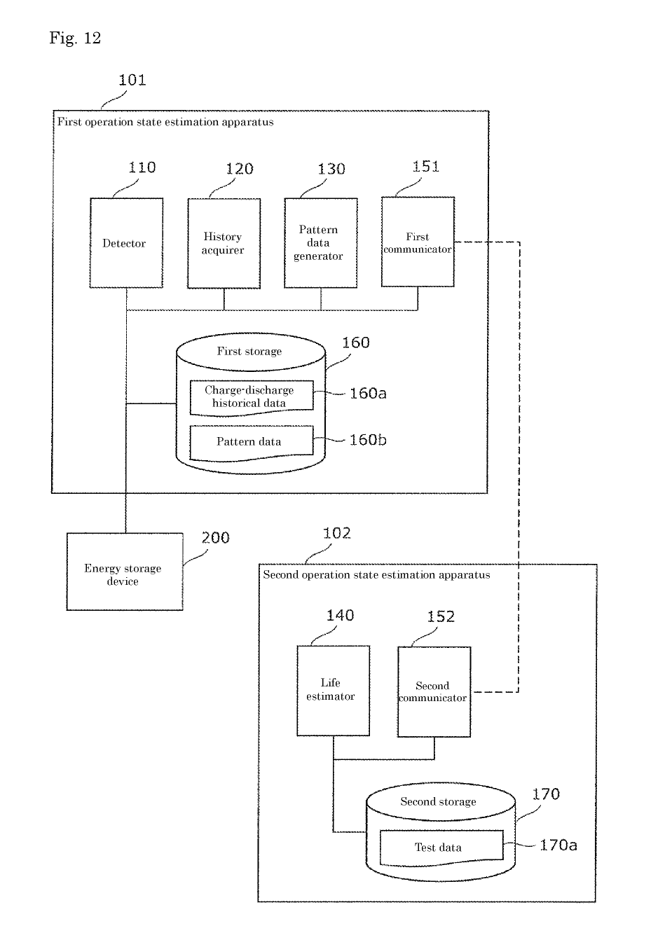

The modification example 1 of the embodiment of the present invention will be described next. FIG. 12 is a block diagram depicting functional configurations of a first operation state estimation apparatus 101 and a second operation state estimation apparatus 102 according to the modification example 1 of the embodiment of the present invention.

As depicted in this figure, the first operation state estimation apparatus 101 includes the detector 110, the history acquirer 120, the pattern data generator 130, and the first storage 160 included in the operation state estimation apparatus 100 according to the above embodiment, and also includes a first communicator 151 in place of the communicator 150.

The second operation state estimation apparatus 102 includes the life estimator 140 and the second storage 170 included in the operation state estimation apparatus 100 according to the above embodiment, and also includes a second communicator 152 in place of the communicator 150.

Similarly to the communicator 150 included in the operation state estimation apparatus 100 according to the above embodiment, the first communicator 151 and the second communicator 152 each function as a processor configured to transmit and receive data to and from external equipment by infrared communication, the Internet, or the like, and transmit and receive data therebetween. For example, the first communicator 151 transmits, to the second communicator 152, pattern data generated by the pattern data generator 130, and the second communicator 152 receives the pattern data from the first communicator 151.

The second communicator 152 functions as an acquirer configured to acquire the pattern data. Specifically, the second communicator 152 acquires pattern data obtained by patterning data indicating repetitive variation out of data indicating variation in state quantity (charge-discharge capacity) of the energy storage device 200 during a predetermined period. The life estimator 140 estimates a life of the energy storage device 200 in accordance with the pattern data acquired by the second communicator 152.

In this manner, the first operation state estimation apparatus 101 is configured to generate pattern data during a predetermined period, whereas the second operation state estimation apparatus 102 is configured to estimate a life of the energy storage device 200 in accordance with the pattern data.

As described above, the first operation state estimation apparatus 101 and the second operation state estimation apparatus 102 according to the present modification example each have divisional functions of the operation state estimation apparatus 100 according to the above embodiment and exert effects similar to those of the above embodiment.

### Modification Example 2

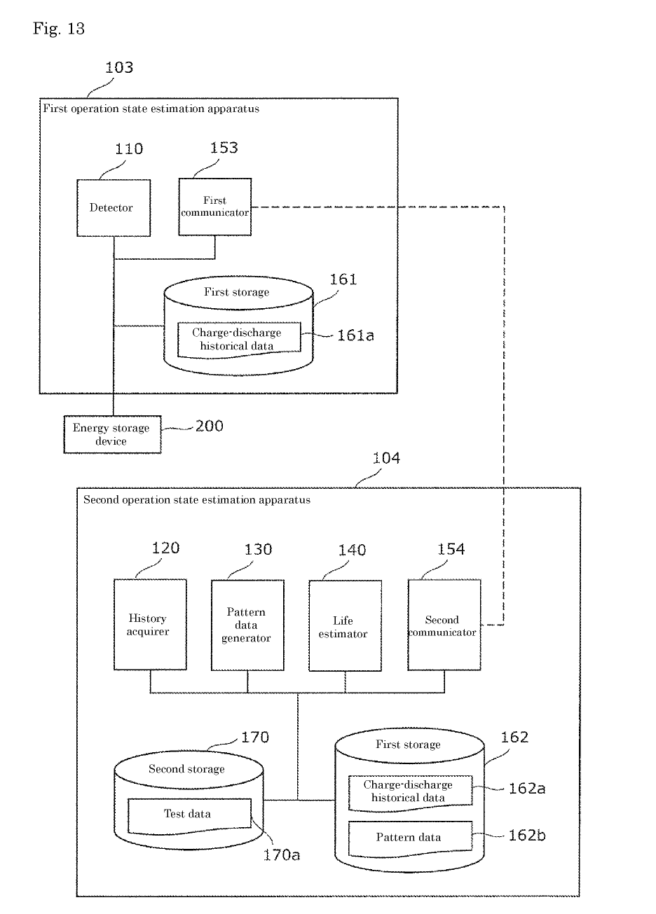

The modification example 2 of the embodiment of the present invention will be described next. FIG. 13 is a block diagram depicting functional configurations of a first operation state estimation apparatus 103 and a second operation state estimation apparatus 104 according to the modification example 2 of the embodiment of the present invention.

As depicted in this figure, the first operation state estimation apparatus 103 includes the detector 110 included in the operation state estimation apparatus 100 according to the above embodiment, and also includes a first communicator 153 and a first storage 161 in place of the communicator 150 and the first storage 160, respectively. The first storage 161 stores charge-discharge historical data 161a.

The second operation state estimation apparatus 104 includes the history acquirer 120, the pattern data generator 130, the life estimator 140, and the second storage 170 included in the operation state estimation apparatus 100 according to the above embodiment, and also includes a second communicator 154 and a first storage 162 in place of the communicator 150 and the first storage 160, respectively. The first storage 162 stores charge-discharge historical data 162a and pattern data 162b.

Similarly to the communicator 150 included in the operation state estimation apparatus 100 according to the above embodiment, the first communicator 153 and the second communicator 154 each function as a processor configured to transmit and receive data to and from external equipment by means of infrared communication, the Internet, or the like, and transmit and receive data therebetween.

The first communicator 153 in the first operation state estimation apparatus 103 transmits, to the second communicator 154, charge-discharge history detected by the detector 110 and written in the charge-discharge historical data 161a.

The first communicator 153 erases, from the charge-discharge historical data 161a in the first storage 161, charge-discharge history transmitted to the second communicator 154. The charge-discharge history is patterned as pattern data by the second operation state estimation apparatus 104 and does not need to be kept in the charge-discharge historical data 161a. The charge-discharge history can thus be erased from the charge-discharge historical data 161a.

The second communicator 154 in the second operation state estimation apparatus 104 receives the charge-discharge history from the first communicator 153 and writes the received charge-discharge history in the charge-discharge historical data 162a. The history acquirer 120 thus acquires the charge-discharge history detected by the detector 110 in the first operation state estimation apparatus 103.

Furthermore, the pattern data generator 130 erases a charge-discharge history acquired by the history acquirer 120 for generation of pattern data from the charge-discharge historical data 162a in the first storage 162. The charge-discharge history is patterned as pattern data and does not need to be kept in the charge-discharge historical data 162a. The charge-discharge history can thus be erased from the charge-discharge historical data 162a.

The charge-discharge historical data 161a stored in the first storage 161 and the charge-discharge historical data 162a stored in the first storage 162 are configured similarly to the charge-discharge historical data 160a stored in the first storage 160 according to the above embodiment and will not be described in detail repeatedly. The pattern data 162b stored in the first storage 162 is also configured similarly to the pattern data 160b stored in the first storage 160 according to the above embodiment and will not be described in detail repeatedly.

The first operation state estimation apparatus 103 is configured to detect a charge-discharge history during a predetermined period, whereas the second operation state estimation apparatus 104 is configured to generate pattern data in accordance with the charge-discharge history and estimate a life of the energy storage device 200.

Described in detail next is the process of acquiring a charge-discharge history of the energy storage device 200 by the history acquirer 120 in the second operation state estimation apparatus 104 (S102 in FIG. 6).

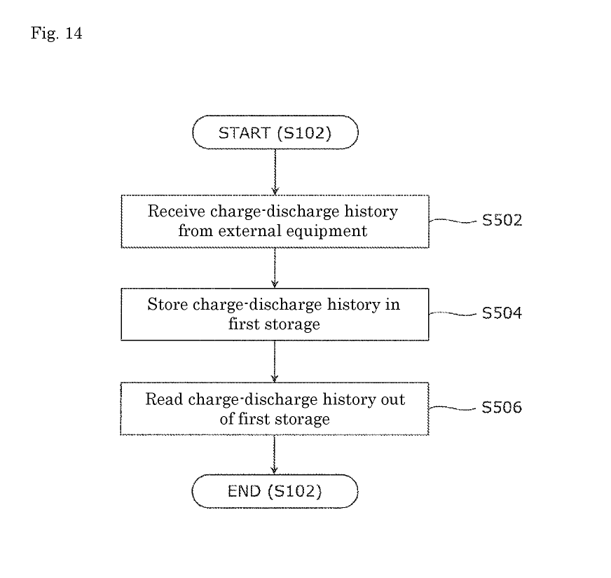

FIG. 14 is a flowchart of an exemplary process of acquiring a charge-discharge history of the energy storage device 200 by the history acquirer 120 according to the modification example 2 of the embodiment of the present invention.

As depicted in this figure, the second communicator 154 initially receives a charge-discharge history from external equipment (S502). Specifically, the second communicator 154 receives a charge-discharge history from the first communicator 153 in the first operation state estimation apparatus 103. Similarly to the above embodiment, the charge-discharge history to be received relates to a date (day/month/year) and time of charge or discharge by the energy storage device 200, a service period of the energy storage device 200, a voltage, a current, a temperature, a battery state, or the like upon charge or discharge by the energy storage device 200.

The second communicator 154 subsequently stores the received charge-discharge history in the first storage 162 (S504). Specifically, the second communicator 154 writes the received charge-discharge history in the charge-discharge historical data 162a stored in the first storage 162.

The history acquirer 120 then reads the charge-discharge history out of the first storage 162 (S506). Specifically, the history acquirer 120 acquires the charge-discharge history received by the second communicator 154 by reading out of the charge-discharge historical data 162a stored in the first storage 162.

Similarly to the above embodiment, the history acquirer 120 reads, out of the charge-discharge historical data 162a, the first information on at least one of a voltage or a current of the energy storage device 200 during a predetermined period, information on a temperature of the energy storage device 200, and information on a service period of the energy storage device 200, and acquires information including these pieces of information, as a charge-discharge history.

As described above, the first operation state estimation apparatus 103 and the second operation state estimation apparatus 104 according to the present modification example each have divisional functions of the operation state estimation apparatus 100 according to the above embodiment and exert effects similar to those of the above embodiment. In particular, the second operation state estimation apparatus 104 according to the present modification example is configured to acquire a charge-discharge history by receiving the charge-discharge history from external equipment. The second operation state estimation apparatus 104 does not need to self-detect any charge-discharge history but is configured to receive a charge-discharge history from external equipment to acquire the charge-discharge history.

### Modification Example 3

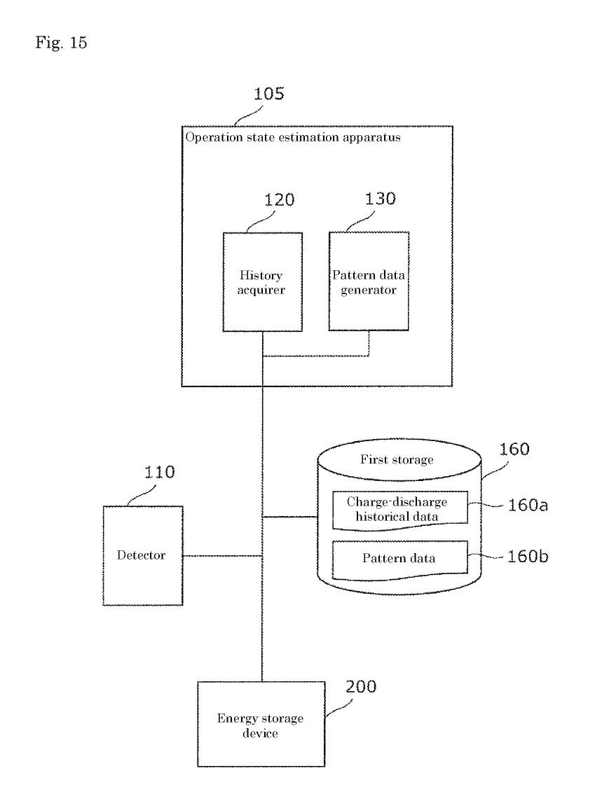

The modification example 3 of the embodiment of the present invention will be described next. FIG. 15 is a block diagram depicting a functional configuration of an operation state estimation apparatus 105 according to the modification example 3 of the embodiment of the present invention. Specifically, this figure is a block diagram depicting a minimum configuration of an operation state estimation apparatus.

As depicted in this figure, the operation state estimation apparatus 105 has only to include the history acquirer 120 and the pattern data generator 130 included in the operation state estimation apparatus 100 according to the above embodiment. The operation state estimation apparatus 105 is configured to communicate with a detector 110, a first storage 160, and the like externally provided, to acquire a charge-discharge history and generate pattern data.

As described above, the operation state estimation apparatus 105 according to the modification example 3 of the embodiment of the present invention also exerts effects similar to those of the above embodiment.

The operation state estimation apparatuses and the energy storage systems according to the embodiment of the present invention and the modification examples thereof have been described above. However, the present invention should not be limited to the embodiment and the modification examples. The embodiment and the modification examples disclosed herein should be regarded as being exemplary and nonlimitative in all aspects. The scope of the present invention is recited not by the above description but by the claims, and is intended to include meanings equivalent to the claims and any modification within the scope.

For example, the history acquirer 120 according to each of the embodiment and the modification examples is configured to acquire, as a charge-discharge history, information including the first information during a predetermined period, information on a temperature of the energy storage device 200, and information on a service period thereof. However, information on a temperature of the energy storage device 200 is not necessarily included in a charge-discharge history acquired by the history acquirer 120. The history acquirer 120 acquires, as a charge-discharge history, information including the first information on at least one of a voltage or a current of the energy storage device 200 and information on a service period of the energy storage device 200. The pattern data generator 130 is configured to generate pattern data in accordance with a relation between the second information on a state quantity (charge-discharge capacity) of the energy storage device 200 obtained from the first information, and information on a service period thereof. In this case, the detector 110 may be configured to detect only information on at least one of a voltage or a current of the energy storage device 200 without detecting information on a temperature of the energy storage device 200, as information on charge or discharge by the energy storage device 200.

In the embodiment and the modification examples thereof, an operation state of the energy storage device 200 is estimated in accordance with a service period of the energy storage device 200. However, in a case where the energy storage device 200 functions as a battery mounted on a vehicle, a service period of the energy storage device 200 is replaceable with a travel distance of the vehicle. In other words, a travel distance of the vehicle may be written in the charge-discharge historical data 160a so that an operation state of the energy storage device 200 is estimated in accordance with the travel distance.

In the embodiment and the modification examples thereof, the pattern data generator 130 is configured to calculate an SOC as the second information on charge-discharge capacity of the energy storage device 200 and generate pattern data. The pattern data generator 130 may be configured to generate pattern data in accordance with a voltage, a current, or the like of the energy storage device 200 as the second information.

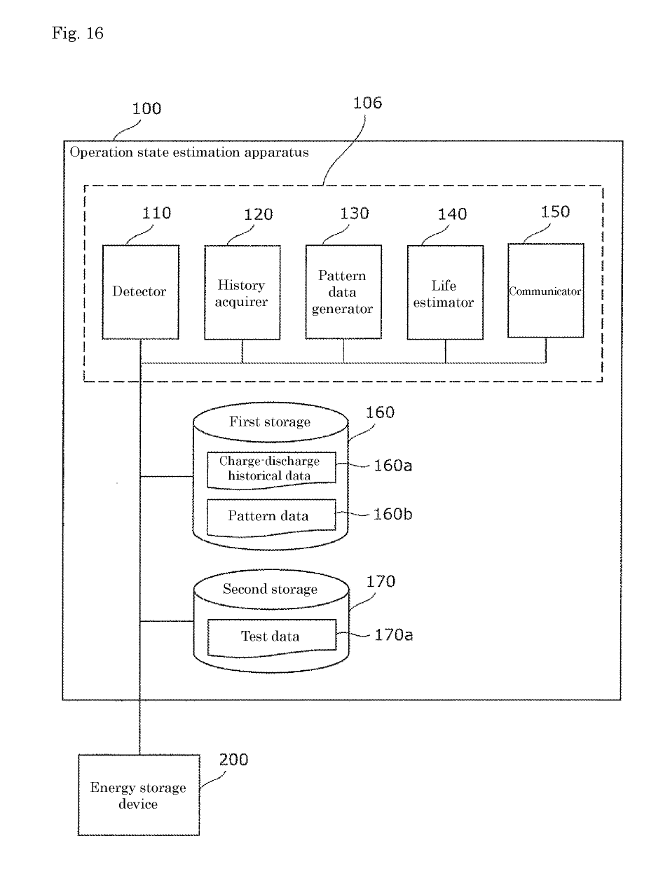

The processors included in the operation state estimation apparatus according to the present invention are typically embodied by a large scale integration (LSI) as an integrated circuit. As exemplified in FIG. 16, the present invention is embodied by an integrated circuit 106 including the detector 110, the history acquirer 120, the pattern data generator 130, the life estimator 140, and the communicator 150. FIG. 16 is a block diagram depicting a configuration, embodied by an integrated circuit, of the operation state estimation apparatus according to the embodiment of the present invention.

The processors included in the integrated circuit 106 can be provided as individual chips or can collectively be provided as a single chip. The LSI herein is alternatively called an IC, a system LSI, a super LSI, or an ultra LSI depending on differences in integration degree.

Circuit integration is not limited to the LSI, but may be embodied by a dedicated circuit or a general purpose processor. A field programmable gate array (FPGA) or a reconfigurable processor in terms of connection or setting of a circuit cell in the LSI may be applied after fabrication of the LSI.

If development in semiconductor technology or different derivative technology leads to technology for circuit integration to replace the LSI, functional blocks can obviously be integrated in accordance with the technology. For example, biotechnology will be possibly applicable.

The present invention is embodied by such an operation state estimation apparatus as well as by an operation state estimation method including steps of the characteristic processes executed by the operation state estimation apparatus.

The present invention is also embodied by a program configured to cause a computer to execute a characteristic process included in the operation state estimation method, and by a computer-readable non-transitory recording medium storing the program, like a flexible disk, a hard disk, a CD-ROM, an MO, a DVD, a DVD-ROM, a DVD-RAM, a Blu-ray (registered trademark) disc (BD), or a semiconductor memory. Such a program is obviously distributable by means of a recording medium like a CD-ROM or through a transmission medium like the Internet.

The scope of the present invention includes any mode obtained by appropriately combining any of the embodiment and the modification examples.

### INDUSTRIAL APPLICABILITY

The present invention is applicable to an operation state estimation apparatus for an energy storage device, and the like, which enable reduction in volume of information accumulated in a memory.

### DESCRIPTION OF REFERENCE SIGNS

10 Energy storage system
100,105 Operation state estimation apparatus
101,103 First operation state estimation apparatus
102,104 Second operation state estimation apparatus
106 Integrated circuit
110 Detector
120 History acquirer
130 Pattern data generator
140 Life estimator
150 Communicator
151,153 First communicator
152,154 Second communicator
160,161,162 First storage
160a,161a,162a Charge-discharge historical data
160b,162b Pattern data
170 Second storage
170a Test data
200 Energy storage device
300 Case

1. An operation state estimation apparatus configured to estimate an operation state of an energy storage device, the apparatus comprising:
a history acquirer configured to acquire a charge-discharge history of the energy storage device during a predetermined period; and
a pattern data generator configured to generate pattern data in accordance with the acquired charge-discharge history, the pattern data being obtained by patterning data indicating repetitive variation out of data indicating variation in state quantity of the energy storage device during the predetermined period.

2. The operation state estimation apparatus according to claim 1, wherein the history acquirer acquires, as the charge-discharge history, information including first information on at least one of a voltage or a current of the energy storage device during the predetermined period and information on a service period of the energy storage device, and
the pattern data generator generates the pattern data in accordance with a relation between second information on the state quantity of the energy storage device obtained from the first information, and the information on the service period of the energy storage device.

3. The operation state estimation apparatus according to claim 2, wherein the history acquirer acquires, as the charge-discharge history, information including the first information during the predetermined period, information on a temperature of the energy storage device, and the information on the service period thereof, and
the pattern data generator generates the pattern data in accordance with a relation among the second information, the information on the temperature, and the information on the service period.

4. The operation state estimation apparatus according to claim 1, further comprising:
a first storage configured to store the charge-discharge history during the predetermined period;
wherein the history acquirer acquires the charge-discharge history by reading out the charge-discharge history stored in the first storage, and
the pattern data generator generates the pattern data in accordance with the acquired charge-discharge history, writes the generated pattern data in the first storage, and erases the acquired charge-discharge history from the first storage.

5. The operation state estimation apparatus according to claim 1, further comprising:
a detector connected to the energy storage device and configured to detect the charge-discharge history from the energy storage device;
wherein the history acquirer acquires the charge-discharge history detected by the detector.

6. The operation state estimation apparatus according to claim 1, further comprising:
a communicator configured to receive the charge-discharge history from external equipment;
wherein the history acquirer acquires the charge-discharge history received by the communicator.

7. The operation state estimation apparatus according to claim 1, further comprising:
a life estimator configured to estimate a life of the energy storage device in accordance with the pattern data.

8. The operation state estimation apparatus according to claim 7, further comprising:
a second storage configured to store test data resulting from a life test of an energy storage device, the test data indicating capacity decrease under a test condition according to the pattern data;
wherein the life estimator estimates a capacity decrease ratio of the energy storage device during the predetermined period by collating the test data with the pattern data generated by the pattern data generator.

9. The operation state estimation apparatus according to claim 8, wherein the life estimator estimates the life of the energy storage device in accordance with the pattern data generated by the pattern data generator and the capacity decrease ratio of the energy storage device during the predetermined period.

10. An operation state estimation apparatus configured to estimate an operation state of an energy storage device, the apparatus comprising:
an acquirer configured to acquire pattern data obtained by patterning data indicating repetitive variation out of data indicating variation in state quantity of the energy storage device during a predetermined period; and
a life estimator configured to estimate a life of the energy storage device in accordance with the acquired pattern data.

11. An energy storage system comprising:
an energy storage device; and
the operation state estimation apparatus according to claim 1, configured to estimate an operation state of the energy storage device.

12. An operation state estimation method of estimating an operation state of an energy storage device, the method being executed by a computer and comprising:
a history acquisition step of acquiring a charge-discharge history of the energy storage device during a predetermined period; and
a pattern data generation step of generating pattern data in accordance with the acquired charge-discharge history, the pattern data being obtained by patterning data indicating repetitive variation out of data indicating variation in state quantity of the energy storage device during the predetermined period.

13. A program configured to cause a computer to execute the steps included in the operation state estimation method for an energy storage device according to claim 12.

14. An integrated circuit configured to estimate an operation state of an energy storage device, the integrated circuit comprising:
a history acquirer configured to acquire a charge-discharge history of the energy storage device during a predetermined period; and
a pattern data generator configured to generate pattern data in accordance with the acquired charge-discharge history, the pattern data being obtained by patterning data indicating repetitive variation out of data indicating variation in state quantity of the energy storage device during the predetermined period.
